(19) United States
(12) Patent Application Publication
(10) Pub. No.: US 2005/0199887 A1
(43) Pub. Date: Sep. 15, 2005

(54) Light emitting device

(75) Inventors: Yoshinobu Suehiro, Aichi-ken (JP); Jun Ito, Aichi-ken (JP)

Correspondence Address: MCGINN & GIBB, PLLC, 8321 OLD COURTHOUSE ROAD, SUITE 200, VIENNA, VA, 22182-3817, US

(73) Assignee: Toyoda Gosei Co., Ltd., Aichi-ken (JP)

(21) Appl. No.: 11/074,939

(22) Filed: Mar. 9, 2005

(30) Foreign Application Priority Data
Mar. 10, 2004 (JP) 2004-067647

(51) Int. Cl. H01L 27/15

(52) U.S. Cl. 257/79; 257/432

(57) ABSTRACT

A light emitting device has an LED element and a transparent material that covers the periphery of the LED element. The LED element has a semiconductor layer that has a light emitting layer and has a refractive index substantially equal to that of the light emitting layer, an electrode to supply electric power to the light emitting layer, a light scattering portion formed in the semiconductor layer, and an optical system that is formed with a convex surface on the semiconductor layer so as to externally radiate light scattered by the light scattering portion. A material composing the light emitting layer to the optical system has a refractive index of 10% or greater than that of the transparent material and of 1.7 or greater.

The present application is based on Japanese patent application No. 2004-067647, the entire contents of which are incorporated herein by reference.

### BACKGROUND OF THE INVENTION

1. Field of the Invention

This invention relates to a light emitting device and, particularly, to a light emitting device that incorporates a light emitting element (herein also referred to as LED element) with enhanced light discharge efficiency to have a high brightness.

2. Description of the Related Art

Conventionally, LED (light emitting diode) elements are composed such that p-type and n-type semiconductor layers including a light emitting layer are formed on a substrate such as a sapphire substrate by using vapor growth methods and a passivation film of SiN etc. is formed thereon so as to protect the semiconductor layers or electrodes.

Japanese patent application laid-open No. 6-291366 (related art 1) discloses an LED element that, instead of using the passivation film, light emitted from its light emitting layer is discharged from a light radiation surface on the side of semiconductor layers (FIG. 1 of the related art 1).

The LED element of the related art 1 is composed such that the GaN based semiconductor layers (with a refractive index of n=2.4) are formed on a sapphire substrate and electrodes are disposed on the side of the light radiation surface. Also, a SnO₂ film (n=1.9) as a transparent electrode is formed on the light radiation surface except a part of the electrodes, and the entire surface is covered with a seal material of epoxy resin (n=1.5) to form a lamp type LED. Prior art 1 mentions that the external quantum efficiency of the LED element can be enhanced since the SnO₂ film prevents the interference of multiple reflection generated in the semiconductor layers while serving as a full-face electrode.

However, the LED element of the related art 1 has problems as described below.

The related art 1 mentions that, when the optical distance (product of optical path length and medium refractive index) of film thickness is one fourth or (2 m+1)4 times (m is an integer) of emission wave, of light to reach the SnO₂ film from the GaN based semiconductor layers, perpendicular incident light can allow an enhancement in external light discharge efficiency since the phase difference between the perpendicular incident light and light reflected at the interface of the epoxy resin and the SnO₂ film helps to reduce the interface reflection light and to increase the interface transmitted light. Also, incident light that enters at an angle to give such an optical distance (the optical distance of light to enter into the SnO₂ film from the GaN based semiconductor layers, reflected on the interface of the epoxy resin and the SnO₂ film, returning to the SnO₂ film and the GaN based semiconductor layers) in the SnO₂ film) that is one fourth or (2m+1)4 times (m is an integer) of emission wave can allow an enhancement in external light discharge efficiency since the phase difference helps to reduce the interface reflection light and to increase the interface transmitted light. However, light entering at such a specific angle into the interface is only a part of the whole lights emitted from the light emitting layer.

On the other hand, light to enter at an angle greater than the critical angle into the SnO₂ film from the GaN based semiconductor layers and to be subjected to total reflection has no effects on the SnO₂ film since return light, which is generated at the interface of the SnO₂ film and the epoxy resin and serves as interference light to the reflected light, does not exist. Provided that light emitted from the light emitting layer is regarded as a perfect diffusion light and externally discharged only from the upper surface, light subjected to total reflection at the interface of the GaN based semiconductor layer and the SnO₂ film accounts for 65% of the total light. Most of the reflected light will be absorbed in the GaN based semiconductor layers. This will be obstructive to the enhancement in external quantum efficiency.

### SUMMARY OF THE INVENTION

It is an object of the invention to provide a light emitting device that incorporates a light emitting element with enhanced light discharge efficiency to have a high brightness.

According to the invention, a light emitting device comprises:
an LED element comprising a semiconductor layer that includes a light emitting layer and has a refractive index substantially equal to that of the light emitting layer, an electrode to supply electric power to the light emitting layer, a light scattering portion formed in the semiconductor layer, and an optical system that is formed with a convex surface on the semiconductor layer so as to externally radiate light scattered by the light scattering portion; and
a transparent material that covers the periphery of the LED element,
wherein a material composing the light emitting layer to the optical system has a refractive index of 10% or greater than that of the transparent material and of 1.7 or greater.

It is preferred that the light scattering portion is disposed corresponding to the optical system.

It is preferred that the light scattering portion is formed below the light emitting layer above which the optical system is formed.

It is preferred that the light emitting device further comprises a substrate on which the semiconductor layer is formed and which has a refractive index substantially different from that of the light emitting layer, wherein the light scattering portion is formed at an interface of the substrate and the semiconductor layer.

It is preferred that the light scattering portion and the optical system comprises a plurality of light scattering portions and optical systems, respectively, which are densely formed.

It is preferred that a passivation film that is formed between the light emitting layer and the optical system.

It is preferred that the electrode comprises a transparent electrode formed between the light emitting layer and the optical system.

It is preferred that the electrode comprises a plurality of electrodes that are formed locally corresponding to a plurality of the optical systems.

It is preferred that the substrate comprises an Al₂O₃ substrate, the semiconductor layer comprises a GaN based semiconductor layer, and the light scattering portion is formed at the interface of the Al₂O₃ substrate and the GaN based semiconductor layer.

It is preferred that the light scattering portion comprises a concave portion formed on the substrate, the concave portion comprising the same material as the semiconductor layer formed on the substrate.

It is preferred that the light scattering portion comprises a convex portion formed on the substrate, the convex portion comprising the same material as the substrate.

It is preferred that the light scattering portion comprises a local region with a plurality of minute concaves and convexes formed on the substrate corresponding to the optical system.

### BRIEF DESCRIPTION OF THE DRAWINGS

The preferred embodiments according to the invention will be explained below referring to the drawings, wherein:

FIG. 1A is a cross sectional view showing a light emitting device in a first preferred embodiment according to the invention;

FIG. 1B is a cross sectional view showing an LED element 10 as a light source in FIG. 1A;

FIG. 1C is a top view showing of the LED element 10 viewed from a direction of C in FIG. 1B;

FIG. 2 is a diagram showing optical paths through which light scattered by a pit 101A in GaN based semiconductor layers is discharged;

FIG. 3A is a cross sectional view showing a modification of a light scattering portion;

FIG. 3B is a cross sectional view showing a modification of a high-refractive index resin portion;

FIG. 4A is a cross sectional view showing an LED element 10 in a second preferred embodiment according to the invention;

FIG. 4B is a top view showing the LED element 10 viewed from a direction of C in FIG. 4A;

FIG. 5 is a cross sectional view showing an LED element in a third preferred embodiment according to the invention; and

FIG. 6 is a cross sectional view showing an LED element in a fourth preferred embodiment according to the invention.

### DETAILED DESCRIPTION OF THE PREFERRED EMBODIMENTS

### First Embodiment

(Composition of Light Emitting Device 1)

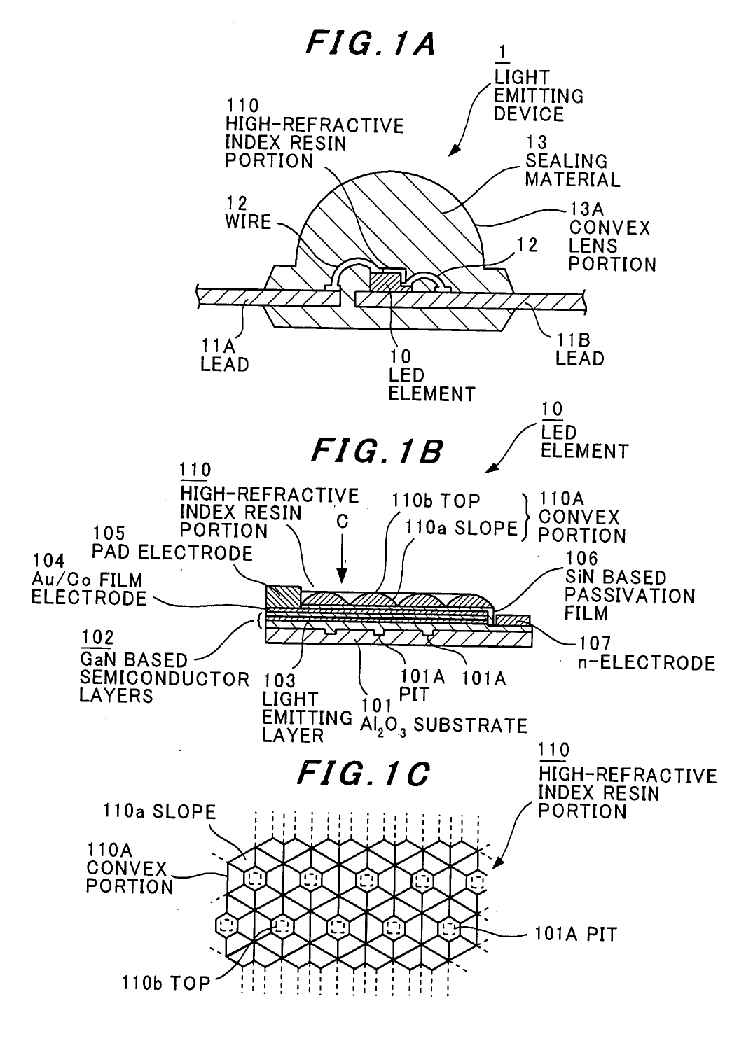

FIG. 1A is a cross sectional view showing a light emitting device in the first preferred embodiment according to the invention. FIG. 1B is a cross sectional view showing an LED element 10 as a light source in FIG. 1A. FIG. 1C is a top view showing of the LED element 10 viewed from a direction of C in FIG. 1B.

The light emitting device 1 is composed of: a face-up type LED element 10 that is made of GaN based semiconductor compound and is provided with a high-refractive index resin portion 110 formed on its top surface; leads 11A, 11B that are made of copper and electrically connected to the LED element 10; wires 12 that are made of Au and connect between the LED element 10 and the leads 11A, 11B; and a sealing material 13 that are made of epoxy resin (n=1.5), forming a transparent material portion to integrally seal the LED element 10, the leads 11A, 11B and the wires 12, and provided with a convex lens portion 13A formed on its upper part.

(Composition of the LED Element 10)

The LED element 10 is, as shown in FIG. 1B, composed of: an Al₂O₃ (sapphire) substrate 101 that is provided with rectangular pits 101A, as the light scattering portion, at the interface of the Al₂O₃ substrate 101 and GaN based semiconductor layers 102; the GaN based semiconductor layers 102 that are formed on the Al₂O₃ substrate 101, including a light emitting layer 103; an Au/Co film electrode 104 that is formed on the GaN based semiconductor layers 102; a pad electrode 105; a SiN passivation film 106 (with a refractive index of n=1.9) that is formed as a transparent protection layer, covering the surface of the LED element 10 except the electrode forming region; an n-electrode 107; and the high-refractive index resin portion 110 that is formed as a thin film layer on the light discharge surface of the LED element 10. The LED element 10 needs to have a refractive index of at least n=1.7 so as to obtain the lens effect when being sealed with the epoxy resin.

The GaN based semiconductor layers 102 are for example composed of: an n-type GaN cladding layer; the light emitting layer 103; a p-type AlGaN cladding layer; and a p-type GaN contact layer, which are epitaxially grown in this order from the side of the Al₂O₃ substrate 101. An AlN buffer layer is formed between the Al₂O₃ substrate 101 and the n-type cladding layer. The GaN based semiconductor layers 102 has a refractive index of n=2.4.

A number of the pits 101A are densely formed concaved by removing the surface of the Al₂O₃ substrate 101 by the irradiation of laser light. GaN based semiconductor is epitaxially grown on the surface of the pits 101A. Instead of removing by the laser light, the pits 101A may be formed such that a photomask corresponding to the formation pattern of the pits 101A is formed on the Al₂O₃ substrate 101 and then the surface is etched.

The light emitting layer 103 is in a multi-quantum well structure composed of a GaN barrier layer and an InGaN well layer, and emits light at a peak emission wavelength of 460 nm.

The high-refractive index resin portion 110 is made of thermosetting resin and with a refractive index of n=2.0 and a thickness of 100 μm. The high-refractive index resin portion 110 A includes number of convex portions 110A that are densely formed on the surface of the light discharge surface of the LED element 10. The convex portion 110A is, as shown in FIG. 1A, formed with seven faces, which have substantially the same area and compose slopes 110a and a top 110b, to be hexagonal. The convex portion 110A is formed by the transferring from a mold made by cutting. The top 110b is disposed corresponding to the pit 101A of the GaN based semiconductor layer 102. The high-refractive index resin portion 110 with the convex portions 110A is formed such that the thermosetting resin film with the convex portions 110A patterned previously by cutting etc. is attached onto the light discharge surface of the LED element 10. The convex portion 110A is provided with such optical surfaces that each of the seven faces has nearly at the center a normal line that passes through slightly over the pit 101A.

Alternatively, the high-refractive index resin portion 110 with the convex portions 110A may be formed, instead of the attaching, by molding a varnish thermosetting resin or by cutting a thermosetting resin formed on the LED element 10.

(Functions)

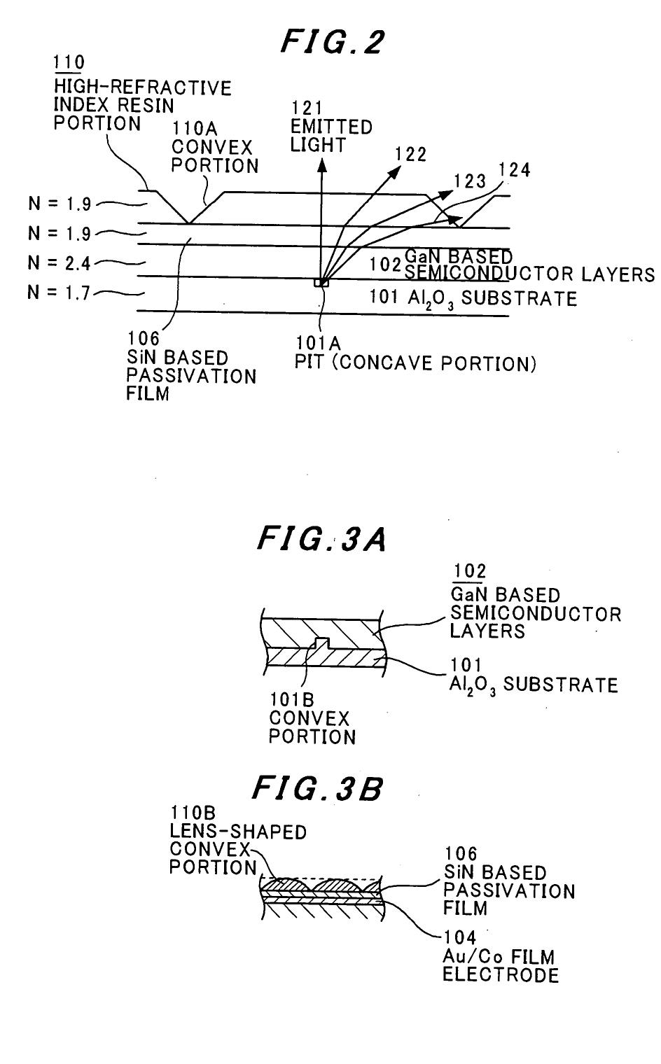

FIG. 2 is a diagram showing optical paths through which light scattered by the pit 101A in the GaN based semiconductor layers 102 is discharged. When the leads 11A, 11B are connected to a power source (not shown) to supply electric power, the LED element 10 emits light from the light emitting layer 103.

Next, the blue light external radiation emitted from the light emitting layer 103 in the GaN based semiconductor layers 102 will be explained classifying it into blue light radiated in the direction of the convex portion 110A, blue light radiated in the direction of the Al₂O₃ substrate 101, and blue light retained in the GaN based semiconductor layers 102.

(Behavior of Blue Light Radiated in the Direction of the Convex Portion 110A)

Blue light to transmit through the GaN based semiconductor layers 102 and to be within a critical angle θ c at the interface of the SiN passivation film 106 and the high-refractive index resin portion 110 enters into the high-refractive index resin portion 110 and is externally radiated as shown in FIG. 2. Thus, emitted lights 121, 122 are externally radiated through the convex portion 110A of the high-refractive index resin portion 110. Also, emitted lights 123, 124 transmit through the SiN passivation film 106, entering into the high-refractive index resin portion 110, externally radiated through the slope 110b of the convex portion 110A.

Thus, by forming the convex portion 110A in the high-refractive index resin portion 110, the external radiation efficiency of blue light entering into the high-refractive index resin portion 110 from various directions can be enhanced since the area of interface (between the high-refractive index resin portion 110 and the sealing material 13) increases as compared to having a flat surface without the convex portion 110A.

(Behavior of Blue Light Radiated in the Direction of the Al₂O₃ Substrate 101)

Blue light to transmit through the GaN based semiconductor layers 102, entering into the Al₂O₃ substrate 101, reflected and scattered at the bottom surface of the Al₂O₃ substrate 101, and heading upward thereby is externally radiated through the convex portion 110A of the high-refractive index resin portion 110 as well as the blue light radiated in the direction of the convex portion 110A.

(Behavior of Blue Light Retained in the GaN Based Semiconductor Layers 102)

Of blue light propagated in the GaN based semiconductor layers 102, light to reach the pit 101A is scattered by the pit 101A and, if being within the critical angle θ c at the interface of the SiN passivation film 106 and the high-refractive index resin portion 110, enters into the high-refractive index resin portion 110 and is externally radiated. In this embodiment, since the convex portion 110A of the high-refractive index resin portion 110 is disposed corresponding to the pit 101A, the incident angle of light to enter into the light discharge surface can be neared to be perpendicular. Thereby, the blue light can be externally radiated at a good efficiency.

(Effects of the First Embodiment)

(1) In the first embodiment, the passivation film is made of SiN, and the high-refractive index resin portion 110 with the convex portion 111A is formed thereon. Thereby, the emission area of blue light can be enlarged. Therefore, the blue light to enter from the GaN based semiconductor layers 102 into the high-refractive index resin portion 110 within the critical angle θ c can be externally radiated at a good efficiency through the convex portion 110A.

(2) Light heretofore confined in the GaN based semiconductor layers 102 can be scattered by the pit 101A and thereby can be externally radiated with a high probability. Due to the scattering of the pit 101A, the pit 101A can be regarded as a substantial light source (pseudo light source). Light from the pseudo light source can have a reduced loss in interface reflection when the shape is made to decrease the incident angle at the interface between the high-refractive index medium and the low-refractive index medium.

Meanwhile, if the optical system is formed with the same refractive index, an ideal external radiation can be realized by a spherical lens with the origin at the pit 101A or its approximate face (e.g., composed of seven faces with substantially the same area and a normal line nearly at the center of each face passing through the pit 101A).

Although in the first embodiment, as a matter of convenience, the layers of the LED element 10 are illustrated thicker than its actual thickness, they are in fact formed very thin so that it is difficult to illustrate them in the same scale as the convex portion 110A of the high-refractive index resin portion 110.

(Modification of the Light Scattering Portion Formed on the Al₂O₃ Substrate 101)

FIG. 3A is a cross sectional view showing a modification of the light scattering portion. In this modification, instead of the pit 101A (concave portion) to scatter blue light emitted from the light emitting layer 103 in the direction of the Al₂O₃ substrate 101, a convex portion 101B is formed as the light scattering portion on the Al₂O₃ substrate 101. The convex portion 101B is, for example, formed by etching a region on the Al₂O₃ substrate 101 except a portion to be the convex portion 101B. By forming the convex portion 101B, blue light propagated in the GaN based semiconductor layers 102 can be discharged in the direction of light discharge surface while being scattered at a good efficiency since the probability of light to reach the light scattering portion with the convex shape increases as compared to the concave shape.

(Modification of the High-Refractive Index Resin Portion 110)

FIG. 3B is a cross sectional view showing a modification of the high-refractive index resin portion 110.

As shown in this modification, a lens-shaped convex portion 110B may be disposed corresponding to the pit 101A of the GaN based semiconductor layers 102. The lens-shaped convex portion 110B is formed a low-profile lens with rounded surface, which corresponds to refraction at the interface of the GaN based semiconductor layers 102 and the SiN based passivation film 106 or at the interface of the SiN based passivation film 106 and the high-refractive index resin portion 110. As compared to a semispherical convex portion with the origin at the pit 101A, the reflection on the interface can be reduced effectively.

Although in the first embodiment the high-refractive index resin portion 110 is formed on the SiN based passivation film 106, the high-refractive index resin portion 110 may be formed directly on the LED element 10 without forming the SiN based passivation film 106.

### Second Embodiment

(Composition of LED Element 10)

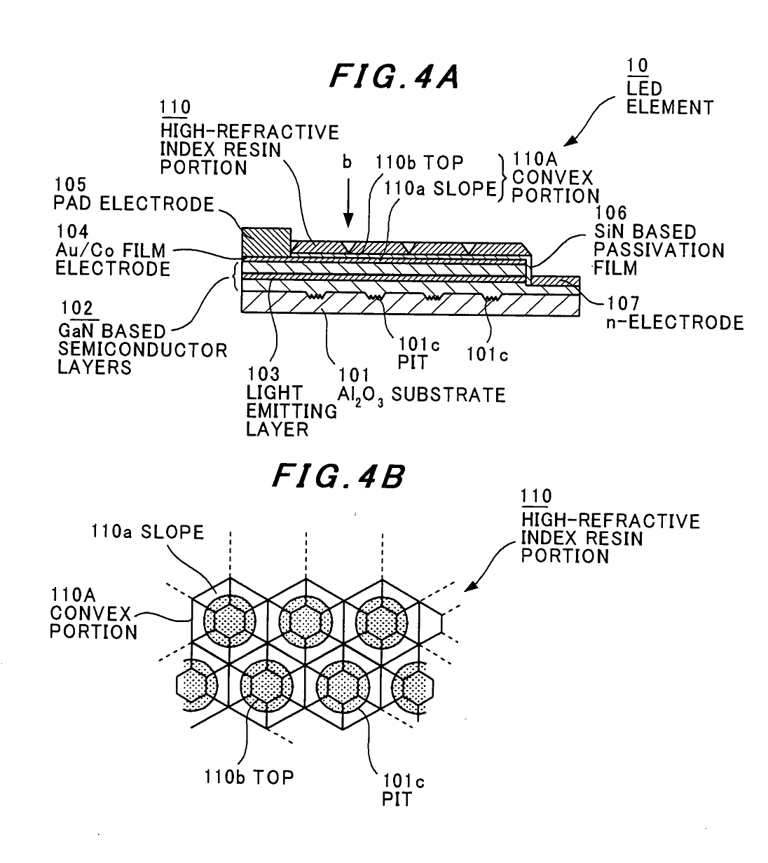

FIG. 4A is a cross sectional view showing an LED element 10 in the second preferred embodiment according to the invention. FIG. 4B is a top view showing the LED element 10 viewed from a direction of C in FIG. 4A.

The LED element 10 of the second embodiment is different from that of the first embodiment in that, as shown in FIG. 4A, a pit 101C as the light scattering portion is formed minute concaves and convexes collected locally on the Al₂O₃ substrate 101. In FIGS. 4A and 4B, like parts are indicated by the same numerals as used in the first embodiment.

The pit 101C is, as shown in FIG. 4B, formed collected in a hexagonal region corresponding to the planar shape of the convex portion 110A of the high-refractive index resin portion 110 formed on the surface of the LED element 10. The end face thereof is roughened.

(Effects of the Second Embodiment)

(1) In addition to the effects of the first embodiment, in the second embodiment, since the end face of the pit 101C is roughened, the scattering property of blue light can be enhanced.

(2) Also, since the pit 101C is formed minute concaves and convexes collected locally on the Al₂O₃ substrate 101, the scattering area of blue light can be enlarged and thereby blue light scattered can more enter into the convex portion 110A of the high-refractive index resin portion 110 within the critical angle thereof. Therefore, the light discharge efficiency from the LED element 10 can be enhanced.

Although the minute concaves and convexes are collected hexagonally in the pit 10C, they may be collected in another shape such as circular and rectangular shapes. Also, the pit 101C may be continuously formed on the Al₂O₃ substrate 101 instead of being formed locally.

### Third Embodiment

(Composition of LED Element 10)

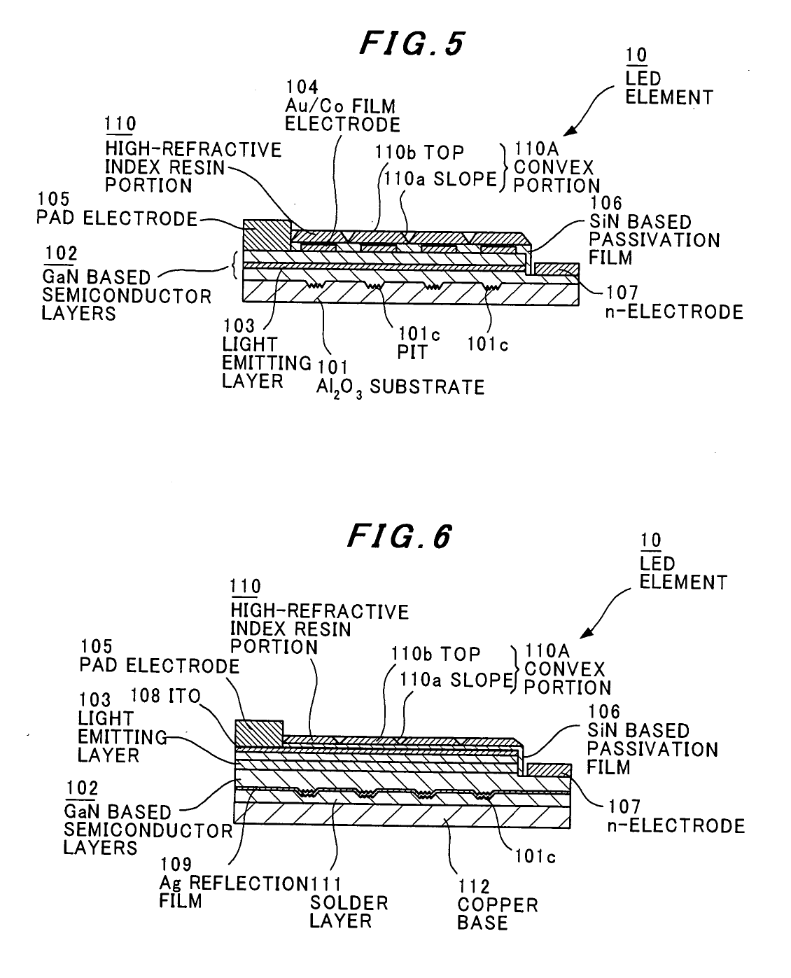

FIG. 5 is a cross sectional view showing an LED element in the third preferred embodiment according to the invention.

The LED element 10 of the third embodiment is different from that of the second embodiment in that, as shown in FIG. 5, the Au/Co film electrode 104 is selectively disposed corresponding to the pit 101C on the Al₂O₃ substrate 101 and the convex portion 110A of the high-refractive index resin portion 110. In FIG. 5, like parts are indicated by the same numerals as used in the second embodiment.

(Effects of the Third Embodiment)

(1) In addition to the effects of the second embodiment, in the third embodiment, since current is mainly supplied from part with the Au/Co film electrode 104 having a resistivity smaller than GaN to the light emitting layer 103, the light emitting layer 103 corresponding to the pit 101C mainly emits blue light. Blue light emitted from the light emitting layer 103 in the direction of the light discharge surface can be externally radiated while entering into the convex portion 110A of the high-refractive index resin portion 110 to lower the reflection loss as well as the pit-scattered light of the second embodiment.

(2) Also, blue light emitted from the light emitting layer 103 in the direction of the Al₂O₃ substrate 101 can be scattered by the pit 101C and radiated in a direction without the Au/Co film electrode 104. Therefore, it can be radiated outside the LED element 10 while lowering the optical absorption by the Au/Co film electrode 104.

### Fourth Embodiment

(Composition of LED Element 10)

FIG. 6 is a cross sectional view showing an LED element in the fourth preferred embodiment according to the invention.

The LED element 10 of the fourth embodiment is different from that of the second embodiment in that, as shown in FIG. 6, an ITO 108 (indium tin oxide: In₂O₃—SnO₂, 90-10 wt %) is used in place of the Au/Co film electrode 104, that the Al₂O₃ substrate 101 is separated from the GaN based semiconductor layers 102 and an Ag reflection film 109 as a light reflection portion is formed on the separation surface, and that a copper base 112 as a heat radiation member is attached through a solder layer 111 onto the surface of the Ag reflection film 109. In FIG. 6, like parts are indicated by the same numerals as used in the second embodiment.

The Ag reflection film 109 is formed a mirror face by depositing Ag on the pit 101C forming surface of the GaN based semiconductor layers 102 that is exposed after the separation of the Al₂O₃ substrate 101.

(Effects of the Third Embodiment)

(1) In addition to the effects of the second embodiment, in the fourth embodiment, the light discharge efficiency from the high-refractive index resin portion 110 can be enhanced while preventing the leak of blue light from the pit 101C forming surface of the GaN based semiconductor layers 102.

(2) By using the ITO 108, the optical absorption can be reduced as compared to using the Au/Co film electrode 104. The lateral propagation light in the GaN based semiconductor layers 102 increases and thereby the blue light scattered by the pit 101C increases. Therefore, the light can be more radiated outside the LED element 10.

(3) Since the copper base 112 with good heat conductivity is integrally formed on the pit 101C forming surface, the heat radiation property can be enhanced. It can be advantageously suited for an increase in brightness and output of the light emitting device.

The copper base 112 as the heat radiation member can be made of another material with good heat conductivity, such as aluminum.

As the electrode material, AZO (ZnO:Al) and IZO (indium zinc oxide: In₂O₃—ZnO, 90-10 wt %) can be used other than the ITO.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

1. A light emitting device, comprising:
an LED element comprising a semiconductor layer that includes a light emitting layer and has a refractive index substantially equal to that of the light emitting layer, an electrode to supply electric power to the light emitting layer, a light scattering portion formed in the semiconductor layer, and an optical system that is formed with a convex surface on the semiconductor layer so as to externally radiate light scattered by the light scattering portion; and
a transparent material that covers the periphery of the LED element,
wherein a material composing the light emitting layer to the optical system has a refractive index of 10% or greater than that of the transparent material and of 1.7 or greater.

2. The light emitting device according to claim 1, wherein:
the light scattering portion is disposed corresponding to the optical system.

3. The light emitting device according to claim 1, wherein:
the light scattering portion is formed below the light emitting layer above which the optical system is formed.

4. The light emitting device according to claim 1 further comprising:
a substrate on which the semiconductor layer is formed and which has a refractive index substantially different from that of the light emitting layer,
wherein the light scattering portion is formed at an interface of the substrate and the semiconductor layer.

5. The light emitting device according to claim 1, wherein:
the light scattering portion and the optical system comprises a plurality of light scattering portions and optical systems, respectively, which are densely formed.

6. The light emitting device according to claim 1 further comprising:
a passivation film that is formed between the light emitting layer and the optical system.

7. The light emitting device according to claim 1, wherein:
the electrode comprises a transparent electrode formed between the light emitting layer and the optical system.

8. The light emitting device according to claim 2, wherein:
the electrode comprises a plurality of electrodes that are formed locally corresponding to a plurality of the optical systems.

9. The light emitting device according to claim 4, wherein:
the substrate comprises an Al₂O₃ substrate,
the semiconductor layer comprises a GaN based semiconductor layer, and
the light scattering portion is formed at the interface of the Al₂O₃ substrate and the GaN based semiconductor layer.

10. The light emitting device according to claim 4, wherein:
the light scattering portion comprises a concave portion formed on the substrate, the concave portion comprising the same material as the semiconductor layer formed on the substrate.

11. The light emitting device according to claim 4, wherein:
the light scattering portion comprises a convex portion formed on the substrate, the convex portion comprising the same material as the substrate.

12. The light emitting device according to claim 4, wherein:
the light scattering portion comprises a local region with a plurality of minute concaves and convexes formed on the substrate corresponding to the optical system.
